(19) United States
(12) Patent Application Publication
(10) Pub. No.: US 2021/0102788 A1
(43) Pub. Date: Apr. 8, 2021

(54) CAPACITIVE DISCHARGE UNIT FOR FIRESET EMPLOYING SILICON CARBIDE THYRISTOR AS HIGH VOLTAGE SWITCH FOR FUZING EVENT

(71) Applicant: HONEYWELL FEDERAL MANUFACTURING & TECHNOLOGIES, LLC, Kansas City, MO (US)

(72) Inventors: Paul Heffernan, Fairway, KS (US); Jake Hamilton, Kansas City, MO (US)

(73) Assignee: HONEYWELL FEDERAL MANUFACTURING & TECHNOLOGIES, LLC, KANSAS CITY, MO (US)

(21) Appl. No.: 16/592,952

(22) Filed: Oct. 4, 2019

(51) Int. Cl. F42B 3/10; H01L 29/74; H01L 29/749; H01L 29/16; H01L 29/872; H03K 17/60

(52) U.S. Cl. CPC F42B 3/10; H01L 29/7408; H01L 29/749; H03K 17/60; H01L 29/7412; H01L 29/872; H01L 29/1608

(57) ABSTRACT

A capacitive discharge unit for a fireset for initiating a fuzing event to detonate an explosive material. The capacitive discharge unit includes a capacitor for storing a voltage, and a silicon carbide thyristor for switching from a high to a low impedance state in response to a triggering pulse, which results in electrical current flowing from the capacitor to the fuzing load. The fireset may further include a controller for providing the triggering pulse to the silicon carbide thyristor. The capacitor stores between 500 V and 1200 V, and the silicon carbide thyristor has a rise time of between 78 ns and 141 ns. The capacitive discharge unit may further include a silicon carbide diode, in the form of a reverse current blocking diode or a Schottkey diode, functioning as a shunt to prevent a reverse current from passing through the switching silicon carbide thyristor.

### GOVERNMENT INTERESTS

This invention was developed with government support under Contract No. DE-NA0000622 awarded by the United States Department of Energy. Accordingly, the U.S. Government has certain rights in the invention.

### FIELD

The present invention relates to switches for electronic firesets, and more particularly, embodiments provide a capacitive discharge unit for an electronic fireset employing a silicon carbide thyristor as a high voltage switch for initiating fuzing to detonate an explosive material.

### BACKGROUND

Firesets initiate fuzing events to detonate explosive materials. Typically, a fireset includes an electronic detonator, which may be a capacitive discharge unit (CDU) or an electronic detonator unit (EDU), and a controller. Initiating a fuzing event requires delivering a large magnitude of electrical current with a very quick rise time to a fuzing load to detonate an explosive material. Currently, there are several types of switches that are capable of delivering the required magnitude of electrical current with a sufficiently quick rise time to initiate fuzing without damaging the switches. Two available switches are the voltage controlled SolidTRON (VCS) and the current controlled SolidTRON (CCS) manufactured by Silicon Power Corporation, both of which utilize silicon as the semiconductor material.

This background discussion is intended to provide information related to the present invention which is not necessarily prior art.

### SUMMARY

Embodiments of the present invention address the above-described and other problems in the prior art by providing a capacitive discharge unit for an electronic fireset employing a silicon carbide thyristor as a high voltage switch for initiating fuzing to detonate an explosive material. Silicon carbide is a large indirect bandgap semiconductor, and has a higher energy density than silicon, which results in the silicon carbide thyristor being capable of switching more energy in a smaller package size than the silicon switches of the prior art.

In a first embodiment of the present invention, a capacitive discharge unit is provided for a fireset for initiating a fuzing event to detonate an explosive material. The capacitive discharge unit may comprise a capacitor for storing a voltage, and a silicon carbide (SiC) thyristor. The SiC thyristor may incorporate silicon carbide as a semiconductor material, and have a gate terminal configured to receive and respond to a trigger signal by switching the SiC thyristor from a high impedance state to a low impedance state which allows electrical current to flow from the capacitor to the fuzing load.

In a second embodiment, a fireset is provided for initiating a fuzing event to detonate an explosive material. The fireset may comprise a capacitive discharge unit and a controller. The capacitive discharge unit may include a capacitor for storing a voltage, and an SiC thyristor. The SiC thyrsitor may incorporate silicon carbide as a semiconductor material, and have a gate terminal configured to receive and respond to a trigger signal by switching the SiC thyristor from a high impedance state to a low impedance state which allows electrical current to flow from the capacitor to the fuzing load. The controller may be configured to transmit the trigger signal to the gate terminal of the SiC thyristor.

Various implementations of the foregoing embodiments may include any one or more of the following additional features. The capacitor may store between 500 volts and 1200 volts, or between 700 volts and 1000 volts. The SiC thyristor may have a rise time of between 78 nanoseconds and 141 nanoseconds, or between 88 nanoseconds and 131 nanoseconds. The capacitive discharge unit may further include an SiC diode incorporating silicon carbide as a semiconductor material, and configured as a shunt to prevent a reverse current from passing through the SiC thyristor when the SiC thyristor is switching. The SiC diode may take the form of a reverse current blocking diode, or a Schottky diode.

This summary is not intended to identify essential features of the present invention, and is not intended to be used to limit the scope of the claims. These and other aspects of the present invention are described below in greater detail.

### DRAWINGS

Embodiments of the present invention are described in detail below with reference to the attached drawing figures, wherein:

FIG. 1 is a cross-sectional elevation depiction of an embodiment of an SiC thyristor constructed in accordance with the present invention;

FIG. 2 is a circuit schematic of a capacitive discharge unit incorporating the SiC thyristor of FIG. 1; and

FIG. 3 is a block diagram of an electronic fireset incorporating the capacitive discharge unit of FIG. 2.

The figures are not intended to limit the present invention to the specific embodiments they depict. The drawings are not necessarily to scale.

### DETAILED DESCRIPTION

The following detailed description of embodiments of the invention references the accompanying figures. The embodiments are intended to describe aspects of the invention in sufficient detail to enable those with ordinary skill in the art to practice the invention. Other embodiments may be utilized and changes may be made without departing from the scope of the claims. The following description is, therefore, not limiting. The scope of the present invention is defined only by the appended claims, along with the full scope of equivalents to which such claims are entitled.

In this description, references to “one embodiment,” “an embodiment,” or “embodiments” mean that the feature or features referred to are included in at least one embodiment of the invention. Separate references to “one embodiment,” “an embodiment,” or “embodiments” in this description do not necessarily refer to the same embodiment and are not mutually exclusive unless so stated. Specifically, a feature, component, action, step, etc. described in one embodiment may also be included in other embodiments, but is not necessarily included. Thus, particular implementations of the present invention can include a variety of combinations and/or integrations of the embodiments described herein.

Broadly characterized, the present invention relates to switches for electronic firesets. More particularly, embodiments provide a capacitive discharge unit for an electronic fireset employing an SiC thyristor as a high voltage switch for initiating fuzing to detonate an explosive material.

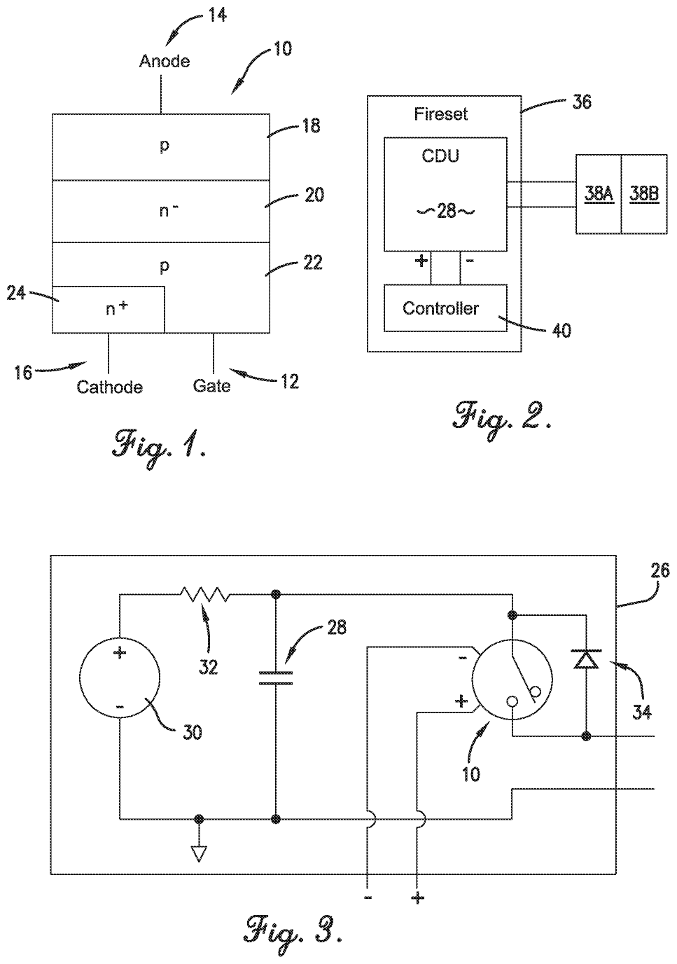

Referring to FIG. 1, an embodiment of an SiC thyristor for controlling a relatively large amount of power and voltage is shown comprising three terminals, a gate 12, an anode 14, and a cathode 16, and four layers, a first P layer 18, an N⁻ layer 20, a second P layer 22, and an N⁺ layer 24, of alternating P and N-type SiC semiconductor material. SiC is a large indirect bandgap semiconductor, and has a higher energy density than silicon, which results in the SiC thyristor 10 being capable of switching more energy in a smaller package size than the silicon switches of the prior art. The SiC thyristor 10 may have a rise time of approximately between 78 ns and 141 ns, or approximately between 88 ns and 131 ns.

Referring also to FIG. 2, an embodiment of a CDU 26 for delivering a large magnitude of electrical current, with a very quick rise time, is shown comprising the SiC thyristor 10, a capacitor 28, a charging source 30, and a charging resistance 32. The capacitor 28 may have a capacitance of approximately between 0.08 uF and 1.0 uF, or approximately between 0.18 uF and 0.9 uF, and store approximately between 500 V and 1200 V, or approximately between 700 V and 1000 V. The charging source 30 and the charging resistance 32 may function in charging the capacitor 28 to the desired voltage. In one implementation, an SiC diode 34 (e.g., an SiC reverse current blocking diode or an SiC Schottky diode) may be used as a shunt to prevent reverse current passing through the SiC thyristor 10 during switching, as seen in FIG. 3.

In operation, the SiC thyristor 10 may be used to maintain a high impedance state and prevent current flow to an output load while the capacitor 28 charges to a specified voltage. Thereafter, the SiC thyristor 10 may receive a trigger signal resulting in the SiC thyristor 10 switching to a low impedance state and an electrical current (which may be approximately between 625 A and 2000 A, or approximately between 825 A and 1400 A) flowing from the capacitor 28 through the SiC thyristor 10 and into the output load. Shortly after switching, i.e., approximately between 1 second and 3 seconds, or approximately 2 seconds, the SiC thyristor 10 may return undamaged to its original high impedance state.

Referring also to FIG. 3, an embodiment of a fireset 36 for initiating a fuzing load 38A to detonate an explosive material 38B is shown comprising the CDU 28 and a controller 40. The controller 40 may be configured to transmit a trigger signal to the gate terminal 12 of the SiC thyristor 10. In operation, the SiC thyristor 10 may be used to maintain a high impedance state and prevent current flow to the fuzing load 38A while the capacitor 28 charges to a specified voltage. Thereafter, the SiC thyristor 10 may receive the trigger signal from the controller 40 resulting in the SiC thyristor 10 switching to a low impedance state and electrical current flowing from the capacitor 28 through the SiC thyristor 10 and into the fuzing load 38A.

Employing an SiC thyristor for this purpose has several advantages over the prior art switches. One advantage is that the SiC thyristor is capable of switching more energy in a smaller package size than the silicon switches of the prior art. Another advantage is that the SiC thyristor has sufficiently high demand in other industries that it is not at risk of reduction in production or becoming obsolete, and further, it is in increasing demand from other industries, which promises increased production and lower per-unit cost, which in turn allows for employing this switch in more products with lower budgets.

Although the invention has been described with reference to the one or more embodiments illustrated in the figures, it is understood that equivalents may be employed and substitutions made herein without departing from the scope of the invention as recited in the claims.

Having thus described one or more embodiments of the invention, what is claimed as new and desired to be protected by Letters Patent includes the following:

1. A capacitive discharge unit for a fireset for initiating a fuzing event to detonate an explosive material, the capacitive discharge unit comprising:
a capacitor for storing a voltage; and
a silicon carbide thyristor incorporating silicon carbide as a semiconductor material, and having a gate terminal configured to receive and respond to a trigger signal by switching the silicon carbide thyristor from a high impedance state to a low impedance state which allows electrical current to flow from the capacitor to the fuzing load.

2. The capacitive discharge unit of claim 1, wherein the capacitor stores between 500 volts and 1200 volts.

3. The capacitive discharge unit of claim 1, wherein the capacitor stores between 700 volts and 1000 volts.

4. The capacitive discharge unit of claim 1, wherein the silicon carbide thyristor has a rise time of between 78 nanoseconds and 141 nanoseconds.

5. The capacitive discharge unit of claim 1, wherein the silicon carbide thyristor has a rise time of between 88 nanoseconds and 131 nanoseconds.

6. The capacitive discharge unit of claim 1, further including a silicon carbide diode incorporating silicon carbide as a semiconductor material and configured as a shunt to prevent a reverse current from passing through the silicon carbide thyristor when the silicon carbide thyristor is switching.

7. The capacitive discharge unit of claim 6, wherein the silicon carbide diode is a reverse current blocking diode.

8. The capacitive discharge unit of claim 6, wherein the silicon carbide diode is a Schottky diode.

9. A fireset for initiating a fuzing event to detonate an explosive material, the fireset comprising:
a capacitive discharge unit including—
a capacitor for storing a voltage, and
a silicon carbide thyristor incorporating silicon carbide as a semiconductor material, and having a gate terminal configured to receive and respond to a trigger signal by switching the silicon carbide thyristor from a high impedance state to a low impedance state which allows electrical current to flow from the capacitor to the fuzing load; and
a controller configured to transmit the trigger signal to the gate terminal of the silicon carbide thyristor.

10. The fireset of claim 9, wherein the capacitor stores between 500 volts and 1200 volts.

11. The fireset of claim 9, wherein the capacitor stores between 700 volts and 1000 volts.

12. The fireset of claim 9, wherein the silicon carbide thyristor has a rise time of between 78 nanoseconds and 141 nanoseconds.

13. The fireset of claim 9, wherein the silicon carbide thyristor has a rise time of between 88 nanoseconds and 131 nanoseconds.

14. The fireset of claim 9, the capacitive discharge unit further including a silicon carbide diode incorporating silicon carbide as a semiconductor material and configured as a shunt to prevent a reverse current from passing through the silicon carbide thyristor when the silicon carbide thyristor is switching.

15. The fireset of claim 14, wherein the silicon carbide diode is a reverse current blocking diode.

16. The fireset of claim 14, wherein the silicon carbide diode is a Schottky diode.

17. A fireset for initiating a fuzing event to detonate an explosive material, the fireset comprising:
a capacitive discharge unit including—
a capacitor for storing a voltage of between 500 volts and 1200 volts, and
a silicon carbide thyristor incorporating silicon carbide as a semiconductor material, and having a rise time of between 78 nanoseconds and 141 nanoseconds, and a gate terminal configured to receive and respond to a trigger signal by switching the silicon carbide thyristor from a high impedance state to a low impedance state which allows electrical current to flow from the capacitor to the fuzing load; and
a controller configured to transmit the trigger signal to the gate terminal of the silicon carbide thyristor.

18. The fireset of claim 17, wherein the voltage is between 700 volts and 1000 volts.

19. The fireset of claim 17, wherein the rise time is between 88 nanoseconds and 131 nanoseconds.

20. The fireset of claim 17, the capacitive discharge unit further including a silicon carbide diode incorporating silicon carbide as a semiconductor material and configured as a shunt to prevent a reverse current from passing through the silicon carbide thyristor when the silicon carbide thyristor is switching.
